(19) United States
(12) Patent Application Publication
(10) Pub. No.: US 2025/0294675 A1
(43) Pub. Date: Sep. 18, 2025

(54) DOUBLE-SIDE ACTIVE METAL BRAZING SUBSTRATE AND METHOD FOR MANUFACTURING THE SAME

(71) Applicant: TONG HSING ELECTRONIC INDUSTRIES, LTD., Taoyuan City (TW)

(72) Inventors: Shao-You Lu, Taoyuan City (TW); Hao-Kun Hsieh, Taoyuan City (TW); Hsin-Hsiang Chiu, Taoyuan City (TW); Ming-Yi Hsu, Taoyuan City (TW); Chi-Wen Huang, Taoyuan City (TW)

(73) Assignee: TONG HSING ELECTRONIC INDUSTRIES, LTD., Taoyuan City (TW)

(21) Appl. No.: 18/764,184

(22) Filed: Jul. 4, 2024

(30) Foreign Application Priority Data
Mar. 14, 2024 (TW) 113109345

(51) Int. Cl. H05K 1/03; H05K 3/38

(52) U.S. Cl. CPC H05K 1/0306; H05K 3/381

(57) ABSTRACT

A double-side active metal brazing substrate includes a ceramic substrate layer, first and second retaining walls, first and second active metal layers, and first and second conductive metal layer. The first active metal layer is disposed on a first surface of the ceramic substrate layer. The first active metal layer is surrounded by the first retaining wall and contacts the first retaining wall. The first conductive metal layer is disposed on the first active metal layer. The second active metal layer is disposed on a second surface of the ceramic substrate layer. The second active metal layer is surrounded by the second retaining wall and contacts the second retaining wall. The second conductive metal layer is disposed on the second active metal layer. The structural design of a thickness of the retaining wall being smaller than a thickness of the active metal layer can prevent a solder from overflowing.

### BACKGROUND OF THE INVENTION

### 1. Field of the Invention

The present invention relates to a double-side active metal brazing substrate and a manufacturing method thereof, and in particular to a double-side active metal brazing substrate with high-precision patterned circuits and a manufacturing method thereof.

### 2. Description of the Prior Art

Driven by the increasing global awareness of energy conservation and carbon reduction and the policies of various countries, electric vehicles have become one of the key research and development projects of car manufacturers. In recent years, car manufacturers have launched a series of 800V high-voltage vehicle models, which has also driven the demand for the characteristics of substrate materials.

Under operating conditions of high voltage, high frequency and high operating temperature, ceramic substrates have higher reliability and heat dissipation capabilities than substrates made of other materials. In the past, the most widely used ceramic substrate was the direct-bonding-copper (DBC) ceramic substrate. However, the traditional DBC ceramic substrate has been unable to meet the packaging requirements of high temperature, high power, high heat dissipation, and high reliability. Therefore, the current mainstream substrate material is gradually shifting from DBC ceramic substrates to active metal brazing (AMB) substrates.

In the manufacturing process of the AMB substrate, a layer of solder is first formed on the surface of the ceramic substrate. A copper layer is coated, and then bonded to the substrate by sintering process. Thereafter, patterned circuits are formed on the ceramic substrate through more than two etching processes. Alternatively, patterned active metal solder may be printed on the surface of the ceramic substrate. A copper layer is coated, and then bonded to the substrate by sintering process. The copper layer is then etched to form patterned circuits. The method of forming patterned active metal solder can not only save the solder in the inactive pattern area and reduce the cost, but also save the subsequent process cost of secondary etching of the solder.

During the high-temperature sintering process, the patterned metal solder is prone to flow. Once the solder overflows into the non-pattern reserved area, it will cause a short circuit. Finally, the second etching performed to remove the solder that overflows into the gaps between patterns does not save the etching cost, which reduces the overall pattern accuracy of the circuit, thereby affecting the product quality.

Therefore, how to prevent solder from overflowing during the sintering process and overcome the above-mentioned defects through structural design or improvement of manufacturing methods has become one of the important issues to be solved in this technical field.

### SUMMARY OF THE INVENTION

It is one object of the present invention to provide a double-side active metal brazing substrate and a manufacturing method thereof in order to solve the shortcomings of the existing technology.

One aspect of the invention provides a double-side active metal brazing substrate including: a ceramic substrate layer having a first surface and a second surface; a first active metal layer disposed on the first surface; a second active metal layer disposed on the second surface; a first retaining wall surrounding and contacting the first active metal layer, wherein a thickness of the first retaining wall is less than a thickness of the first active metal layer; a second retaining wall surrounding and contacting the second active metal layer, wherein a thickness of the second retaining wall is less than a thickness of the second active metal layer; a first conductive metal layer disposed on the first active metal layer; and a second conductive metal layer disposed on the second active metal layer.

According to some embodiments, a thickness ratio of the first retaining wall to the first active metal layer is 0.10 to 0.95.

According to some embodiments, the first retaining wall comprises aluminum oxide, magnesium oxide, zirconium oxide, silicon oxide, aluminum nitride or silicon nitride.

According to some embodiments, a thickness of the first retaining wall is 1-5 micrometers.

According to some embodiments, a width of the first retaining wall is 0.1 mm to 30 mm.

According to some embodiments, a thickness of the first active metal layer is 10-50 micrometers.

Another aspect of the invention provides a method for manufacturing a double-side active metal brazing substrate including performing a patterning process to form a first retaining wall on a first surface of a ceramic substrate layer, and a second retaining wall on a second surface of the ceramic substrate layer, wherein the first retaining wall defines a first patterned area, and the second retaining wall defines a second patterned area; forming a first active metal layer in the first patterned area, and forming a second active metal layer in the second patterned area; disposing a first conductive metal layer on the first active metal layer, and disposing a second conductive metal layer on the second active metal layer; and performing a brazing process to fix the first conductive metal layer to the ceramic substrate layer, and fix the second active metal layer to the ceramic substrate layer. A thickness of the first retaining wall is less than a thickness of the first active metal layer, and a thickness of the second retaining wall is less than a thickness of the second active metal layer.

According to some embodiments, a sintering temperature in the brazing process is 800-950° C.

According to some embodiments, a sintering pressure in the brazing process is less than 8×10⁻⁵ Torr.

According to some embodiments, a tensile strength of the double-side active metal brazing substrate is greater than 100 N/cm.

One of the beneficial effects of the present invention is that the double-side active metal brazing substrate and the manufacturing method thereof provided by the present invention can prevents solder from overflowing at high temperatures by virtue of the technical solution of “the retaining wall” and “the thickness of the retaining wall is lower than the thickness of the active metal layer”, thereby improving the bonding force between the ceramic substrate layer and the conductive metal layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic side view of a double-side active metal brazing substrate according to one embodiment of the present invention.

FIG. 2 is a schematic diagram showing the step of setting a retaining wall on a ceramic substrate layer according to the present invention.

FIG. 3 is a schematic diagram showing the step of setting an active metal layer on a ceramic substrate layer according to the present invention.

FIG. 4 is a schematic diagram showing the step of disposing a conductive metal layer on an active metal layer according to the present invention.

FIG. 5 is a schematic side view of a double-side active metal brazing substrate according to another embodiment of the present invention.

### DETAILED DESCRIPTION

The following is a specific example to illustrate the implementation of the “double-side active metal brazing substrate and a manufacturing method thereof” disclosed in the present invention. Those skilled in the art can understand the advantages and effects of the present invention from the content disclosed in this specification. The present invention can be implemented or applied through other different specific embodiments, and various details in this specification can also be modified and changed based on different viewpoints and applications without departing from the concept of the present invention. In addition, the drawings of the present invention are only simple schematic illustrations and are not depictions based on actual dimensions, as is stated in advance. The following embodiments will further describe the relevant technical content of the present invention in detail, but the disclosed content is not intended to limit the scope of the present invention. In addition, the term “or” used in the specification includes any one or combination of multiple associated listed items, depending on the actual situation.

In order to prevent the solder from overflowing from the edge of the pattern to the non-pattern reserved area during the sintering process, it is one technical feature of the present invention to dispose a retaining wall on the ceramic substrate layer to define the patterned area, and then form the active metal solder in the patterned area. The retaining wall can prevent the active metal solder from overflowing during the brazing process, ensure that the double-side active metal brazing substrate has a high-precision circuit pattern, and eliminate the need of secondary etching of the excess solder.

It is another technical feature of the present invention that the thickness of the retaining wall is controlled. According to the experimental results, in high-temperature environments, the material of the retaining wall may react with the active metal solder, thereby adversely affecting the bonding force between the active metal solder and the subsequent conductive metal layer. Therefore, by controlling the thickness of the retaining wall, the double-side active metal brazing substrate can have higher tensile strength.

In this disclosure, a double-side active metal brazing substrate means that the opposite sides of the substrate are provided with conductive metal layers. It should be noted that the conductive metal layers on both sides may have the same or different patterns. For example, the conductive metal layer on one side can be used as a circuit layer, and the conductive metal layer on the other side can be used as a heat dissipation layer. Alternatively, the conductive metal layers on both sides can be used as circuit layers. However, the present invention is not limited thereto.

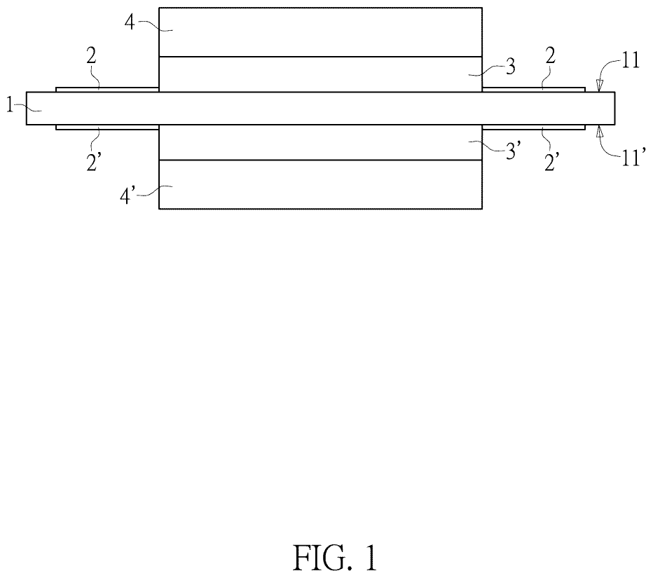

Please refer to FIG. 1. The double-side active metal brazing substrate of the present invention includes: a ceramic substrate layer 1, a first retaining wall 2, a second retaining wall 2′, a first active metal layer 3, a second active metal layers 3′, a first conductive metal layer 4 and a second conductive metal layer 4′.

The first retaining wall 2, the first active metal layer 3 and the first conductive metal layer 4 are disposed on the first surface 11 of the ceramic substrate layer 1, the second retaining wall 2′, the second active metal layer 3′ and the second conductive metal layer 4″ is disposed on the second surface 11′ of the ceramic substrate layer 1. The structure of each layer in the double-side active metal brazing substrate will be described below.

### Ceramic Substrate Layer

The ceramic substrate layer 1 is a substrate that can be used to carry double-side printing structures, which may comprise a silicon nitride (Si₃N₄) ceramic substrate, a silicon carbide (SiC) ceramic substrate, an aluminum nitride (AlN) ceramic substrate, or an aluminum oxide (Al₂O₃) ceramic substrate, preferably, a silicon-containing ceramic substrate, more preferably, a silicon nitride ceramic substrate. In addition, the thickness of the ceramic substrate layer 1 may be 0.25 mm to 1 mm, but not limited thereto.

### Retaining Wall

The retaining wall is disposed on the ceramic substrate layer 1. The retaining wall can define a patterned area on the ceramic substrate layer 1. This patterned area can be designed or adjusted according to the pattern structure of the active metal layer and the conductive metal layer.

In the structure shown in FIG. 1, the first retaining wall 2 is disposed on the first surface 11 and defines a patterned area. The range of the patterned area can be designed or adjusted according to the pattern structures of the first active metal layer 3 and the first conductive metal layer 4. Similar to the first retaining wall 2, the second retaining wall 2′ is disposed on the second surface 11′ to define another patterned area. The range of this patterned area can be designed or adjusted according to the pattern structure of the second active metal layer 3′ and the second conductive layer 4′.

Since the conductive metal layers on both sides of the ceramic substrate layer may have the same or different pattern patterns, the patterned area defined by the first retaining wall 2 may be the same as or different from the patterned area defined by the second retaining wall 2′.

The retaining wall can prevent the active metal layer from overflowing the patterned area in a high-temperature environment (such as a brazing process), so as to produce a double-side active metal brazing substrate with high-precision patterned circuits.

In order to prevent the active metal layer from overflowing the patterned area, the retaining wall is composed of a highly heat-resistant material, and a material of the retaining wall has a low affinity with a material of the active metal layer. Even if the active metal layer material in the molten state contacts the retaining wall, the active metal layer material will not accumulate beyond the patterned area defined by the retaining wall due to its large cohesion.

Specifically, the material of the retaining wall may be aluminum oxide (Al₂O₃), magnesium oxide (MgO), zirconium oxide (ZrO₂), silicon oxide (SiO₂), aluminum nitride (AlN) or silicon nitride (Si₃N₄). For example, the retaining wall can be composed of particles of the above-mentioned high heat-resistant material. The retaining wall composed of particles can make the material of the retaining wall have a lower affinity with the material of the active metal layer. For example, the average particle size of the particles is less than 12 micrometers. In an exemplary embodiment, the average particle size of the particles is 3-12 micrometers, for example, a positive integer between 3-12 micrometers.

Furthermore, in order to achieve a good barrier effect, the width of the retaining wall can be further controlled. When the width of the retaining wall is wider, it is more difficult for the active metal layer material to cross the retaining wall beyond the patterned area. In an exemplary embodiment, the width of the retaining wall is 0.1 mm to 30 mm. For example, the width of the retaining wall may be a positive integer between 0.1 mm and 30 mm.

Regarding the thickness of the retaining wall, the experimental results show that in a high temperature environment, the material of the retaining wall may react with the material of the active metal layer at the contact surface, or may diffuse to the upper surface of the active metal layer.

Specifically, the original purpose of the active metal layer is to combine with the conductive metal layer. However, when the material of the active metal layer reacts with the material of the retaining wall, or diffuses to the contact surface between the active metal layer and the conductive metal layer, the bonding force between the material of the active metal layer and the material of the conductive metal layer may be reduced. Therefore, it is another technical feature of the present invention to further control the thickness of the retaining wall to be lower than the thickness of the active metal layer, in order to prevent the active metal layer from overflowing the patterned area without reducing the bonding force of the conductive metal layer.

To facilitate the definition of the thickness of each layer, in this disclosure, the thickness of the first retaining wall 2 and the thickness of the first active metal layer 3 refer to the direction perpendicular to the first surface 11. The thickness of the second retaining wall 2′ and the thickness of the second active metal layer 3′ refer to the direction perpendicular to the second surface 11′.

In addition, by controlling the thickness ratio of the retaining wall to the active metal layer, the present invention enables the double-side active metal brazing substrate to have good pattern circuit accuracy without adversely affecting the bonding force between the material of the active metal layer and the material of the conductive metal layer. Specifically, the thickness ratio of the first retaining wall 2 to the first active metal layer 3 is 0.10-0.95. For example, the thickness ratio of the first retaining wall 2 to the first active metal layer 3 may be 0.15, 0.20, 0.25, 0.30, 0.35, 0.40, 0.45, 0.50, 0.55, 0.60, 0.65, 0.70, 0.75, 0.80, 0.85 or 0.90. The thickness ratio of the second retaining wall 2′ to the second active metal layer 3′ is 0.10-0.95. For example, the thickness ratio of the second retaining wall 2′ to the second active metal layer 3′ may be 0.15, 0.20, 0.25, 0.30, 0.35, 0.40, 0.45, 0.50, 0.55, 0.60, 0.65, 0.70, 0.75, 0.80, 0.85 or 0.90.

In an exemplary embodiment, the thickness of the first retaining wall 2 is 1-5 micrometers, and the thickness of the second retaining wall 2′ is 1-5 micrometers.

In order to achieve the above thickness design of the retaining wall, the retaining wall can be disposed on the ceramic substrate layer 1 through screen printing. However, the manner of arranging the retaining wall is not limited to this. As long as the thickness of the retaining wall can be made thinner than the thickness of the active metal layer, it can be applied in the present invention.

### Active Metal Layer

The active metal layer is disposed in the patterned area defined by the retaining wall, and the active metal layer is disposed between the ceramic substrate layer 1 and the conductive metal layer to fix the conductive metal layer on the ceramic substrate layer 1.

In the structure shown in FIG. 1, the first active metal layer 3 is disposed in the patterned area defined by the first retaining wall 2, that is, the first retaining wall 2 surrounds the first active metal layer 3. In order to control the shape of the circuit layer more accurately, the first retaining wall 2 can be in contact with the side of the first active metal layer 3 to prevent the active metal solder from overflowing the patterned area in a high temperature environment.

Similar to the first active metal layer 3, the second active metal layer 3′ is disposed in the patterned area defined by the second retaining wall 2′, that is, the second retaining wall 2′ surrounds the second active metal layer 3′. Furthermore, the second retaining wall 2′ can be in contact with the side of the second active metal layer 3′ to prevent the active metal solder from overflowing the patterned area in a high temperature environment.

The active metal layer is formed from an active metal solder paste. The active metal solder paste includes an active metal solder and an organic dispersion medium, and the active metal solder is dispersed in the organic dispersion medium. Under high temperature conditions, the active metal solder can form an alloy with the material of the ceramic substrate layer, and can also form an alloy with the material of the conductive metal layer to achieve a bonding effect.

The active metal solder includes metal silver (Ag), metal copper (Cu) and active metals. Specifically, the active metal may be selected from the group consisting of: metal titanium (Ti), metal zirconium (Zr), metal tantalum (Ta), metal niobium (Nb), metal vanadium (V) and metal hafnium (Hf). In a preferred embodiment, the active metal solder includes metal silver (Ag), metal copper (Cu) and metal titanium (Ti). In a high-temperature environment (brazing process), some metals can diffuse into the ceramic substrate to form metal silicon compounds or metal nitrogen compounds; some metals can also diffuse into the conductive metal layer to form alloys to enhance the mutual bonding effect.

As explained above, by coating the active metal layer in the patterned area surrounded by the retaining wall and controlling the thickness of the active metal layer to be higher than the thickness of the retaining wall, the double-side active metal brazing substrate of the present invention can have a higher tensile strength.

As the thickness of the active metal layer increases, the bonding force between the ceramic substrate layer and the conductive metal layer will also increase. However, when the thickness of the active metal layer is too thick, the material cost of the active metal layer will be too high, which is not conducive to mass production. Therefore, the thickness of the active metal layer 2 is greater than or equal to 6 micrometers. If the thickness of the active metal layer is not lower than the retaining wall and does not cause process cost problems, the thickness of the active metal layer can be 10-50 micrometers. For example, the thickness of the active metal layer 2 may be a positive integer between 10-50 micrometers.

### Conductive Metal Layer

The conductive metal layer is disposed on the active metal layer. Since the bonding force between the conductive metal layer and the ceramic substrate layer 1 is weak, the conductive metal layer needs to be disposed on the ceramic substrate layer through the active metal layer.

Through different structural designs, the conductive metal layer can be used as the circuit layer or heat dissipation layer of the active metal brazing substrate. When used as a circuit layer, the pattern accuracy of the conductive metal layer will have a great impact on the quality of the double-side active metal brazing substrate.

In the structure shown in FIG. 1, the first conductive metal layer 4 is fixed on the first surface 11 of the ceramic substrate layer 1 through the first active metal layer 3. The pattern structure of the first conductive metal layer 4 corresponds to the pattern structure the first active metal layer 3. Similar to the first conductive metal layer 4, the first conductive metal layer 4′ is disposed on the second surface 11′ of the ceramic substrate layer 1 through the second active metal layer 3′. The pattern structure of the second conductive metal layer 4′ corresponds to the pattern structure of the first conductive metal layer 4′.

Specifically, the conductive metal layer may be a metal copper foil, a metal aluminum foil or a copper-aluminum alloy foil. In a preferred embodiment, the conductive metal layer is preferably a metal copper foil.

Since the bonding force between the ceramic substrate layer and the conductive metal layer of the present invention is better, thicker conductive metal layers can be soldered, and the thickness of the conductive metal layer can be 0.2 mm to 1.5 mm, such as: 0.3 mm, 0.4 mm, 0.5 mm, 0.6 mm, 0.7 mm, 0.8 mm, 0.9 mm, 1.0 mm, 1.1 mm, 1.2 mm, 1.3 mm or 1.4 mm.

### Manufacturing Method of Double-Side Active Metal Brazing Substrate

The manufacturing method of the double-side active metal brazing substrate of the present invention includes sequentially forming a retaining wall (patterning process), an active metal layer (coating process, drying process) and a conductive metal layer on the ceramic substrate layer, and then performing brazing process to complete a double-side active metal brazed substrate.

As mentioned above, the retaining wall, the active metal layer and the conductive metal layer are formed on opposite sides of the ceramic substrate layer. In actual operation, according to the requirements, the retaining walls can be formed on the first surface and the second surface of the ceramic substrate layer, and then the active metal layers and the conductive metal layers are sequentially provided on the first surface and the second surface. In some embodiments, a retaining wall, an active metal layer and a conductive metal layer may be sequentially formed on the first surface of the ceramic substrate layer, and a retaining wall, an active metal layer and a conductive metal layer are then sequentially formed on the second surface of the ceramic substrate layer.

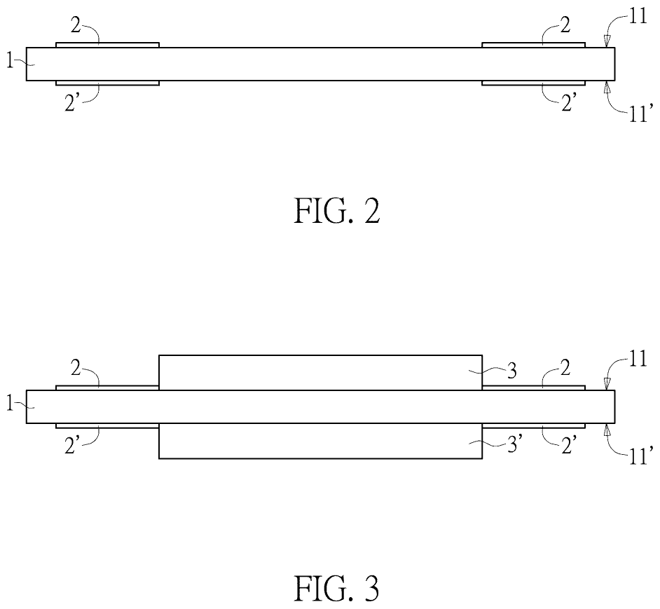

In Step S1, a patterning process is performed to form a retaining wall on the ceramic substrate layer. The structural design of the retaining wall defines a patterned area, as shown in FIG. 2.

That is to say, a first retaining wall is formed on the first surface of the ceramic substrate layer, and the first retaining wall defines the first patterned area. A second retaining wall is formed on the second surface of the ceramic substrate layer, and the second retaining wall defines a second patterned area. For convenience of explanation, the manufacturing method of the double-side active metal brazing substrate will be described below with general terms, but the present invention is not limited to this.

In the patterning process, the retaining wall may be formed by screen printing, but not limited thereto.

In Step S2, a preparation process is performed to prepare an active metal solder paste. The active metal solder paste is used to form the aforementioned active metal layer, and the active metal solder paste contains the aforementioned active metal solder and an organic dispersion medium.

The active metal solder includes the aforementioned metal silver, metal copper and active metals. In some embodiments, the active metal solder is a combination of metal silver powder, metal copper powder and metal titanium powder. In some other embodiments, the active metal solder may be a combination of at least one of metal silver powder, metal copper powder, and silver-copper alloy powder, and active metal powder.

Taking the total weight of the active metal solder as 100% by weight, the content of metal silver in the active metal solder is 10% to 60% by weight, the content of metal copper is 30% to 80% by weight, and the content of active metal is 1% to 10% by weight.

The organic dispersion medium can help disperse the active metal solder and help shape the active metal solder paste to form an active metal layer. Specifically, the organic dispersion medium includes paste-forming agent, organic solvent and thixotropic agent. Taking the total weight of the organic dispersion medium as 100% by weight, the content of the paste-forming paste is 20% to 30% by weight, the content of the organic solvent is 50% to 70% by weight, and the content of the thixotropic agent is 1% to 5% by weight. However, the present invention is not limited thereto, as long as the active solder powder and organic components can be formulated into an active solder with a viscosity suitable for coating on the ceramic substrate layer to facilitate the formation of the active metal layer.

In Step S3, a coating process is performed to coat the active metal solder paste on the patterned area. In the coating process, active metal solder paste can be applied to the patterned area by screen printing.

In Step S4, a drying process is performed to form an active metal layer from the active metal solder paste. In the drying process, the active metal solder paste is dried at a temperature of 90-110° C. for 5-15 minutes to volatilize most of the organic solvent in the active metal solder paste, thereby forming an active metal layer, as shown in FIG. 3.

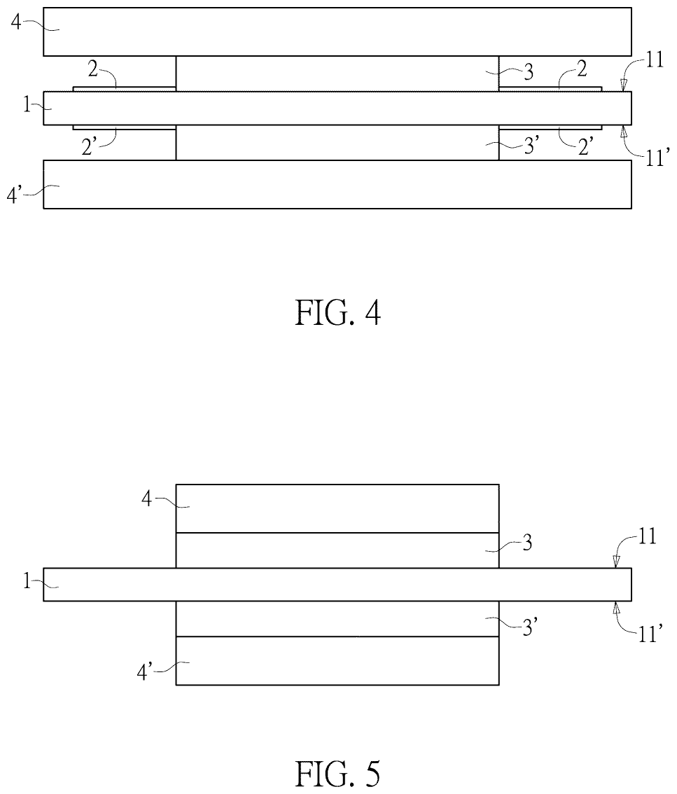

In Step S5, as shown in FIG. 4, the conductive metal layer is disposed on the active metal layer.

In Step S6, a brazing process is performed to connect the conductive metal layer to the active metal layer and fix it to the ceramic substrate layer.

In the brazing process, a first-stage heat treatment process and a second-stage heat treatment process can be performed sequentially under a vacuum degree of less than or equal to 8×10⁻⁵ Torr. The temperature condition of the first-stage heat treatment process is 800-890° C., and the temperature condition of the second-stage heat treatment program is from 900-1100° C. (i.e., the temperature range of brazing). The temperature of the second-stage heat treatment process is higher than the temperature of the first-stage heat treatment process, and is kept at the highest temperature for 30 minutes.

In a preferred embodiment, the temperature ramp rate of the above heat treatment process may be, for example, 5° C./min to 30° C./min. The cooling rate after the brazing process can be, for example, 2° C./min to 30° C./min.

After the conductive metal layer is provided, an etching process can be selectively performed to remove the conductive metal layer outside the patterned area to achieve patterning and form a final product, as shown in FIG. 1.

In some embodiments, during the etching process, the retaining wall may also be removed along with the conductive metal layer outside the patterned area, thereby obtaining a double-side active metal brazing substrate as shown in FIG. 5. This step is optional and the retaining wall may not be removed.

In order to verify that the double-side active metal brazing substrate of the present invention has high-precision pattern circuits, the double-side active metal brazing substrates of Examples 1 to 3 and the single-side active metal brazing substrates of Comparative Examples 1 to 3 were prepared according to the above Steps S1-S6.

### Examples 1 to 3

In the double-side active metal brazing substrates of Examples 1 to 3, the ceramic substrate layer is a silicon nitride ceramic substrate. The material of the first retaining wall and the second retaining wall is aluminum oxide. The materials of the first active metal layer and the second active metal layer include metal silver, metal copper and metal titanium. The total weight of the active metal solder is 100% by weight, the content of metal silver is 70% by weight, the content of metal copper is 25% by weight, and the content of metal titanium is 5% by weight. The first conductive metal layer and the second conductive metal layer are metal copper foils.

The differences between Examples 1 to 3 include: the thicknesses of the active metal layer are different, and the thickness ratios of the retaining wall to the active metal layer are also different.

In the brazing process, the vacuum degree is less than or equal to 8×10⁻⁵ Torr, the temperature condition of the first-stage heat treatment process is 855° C., the temperature condition of the second-stage heat treatment process is 915° C., and is maintained at the highest temperature for 30 minutes.

After the active metal brazing substrate is prepared, the thickness of the retaining wall, the thickness of the active metal layer, the printing position and the results of whether the solder diffuses after brazing in Examples 1 to 3 are listed in Table 1. Furthermore, at a temperature of 25° C., the tensile strength of the active metal brazing substrate was measured according to the JIS-C-6481 standard, and the results are listed in Table 1.

### Comparative Examples 1 to 3

The single-side active metal brazing substrates in Comparative Examples 1 to 3 are made using a manufacturing method similar to the double-side active metal brazing substrate in Example 1. Comparative Examples 1 to 3 only have layers on single side of the ceramic substrate layer. Furthermore, in Comparative Examples 1 and 2, the thickness of the retaining wall was higher than the thickness of the active metal layer, and in Comparative Example 3, no retaining wall was provided.

After preparing the active metal brazing substrate, the thickness of the retaining wall, the thickness of the active metal layer, the printing position and the results of whether the solder diffuses after brazing in Comparative Examples 1 to 3 are listed in Table 1. Furthermore, at a temperature of 25° C., the tensile strength of the active metal brazing substrate was measured according to the JIS-C-6481 standard, and the results are listed in Table 1.

TABLE 1

| | | | Ratio of | | | |
|---|---|---|---|---|---|---|
| | | | retaining | | | |
| | Active | | wall | | | |
| | metal | Retaining | thickness | | | |
| | layer | wall | to active | | | Tensile |
| | thickness | thickness | metal layer | Printing | Solder | strength |
| | (μm) | (μm) | thickness | position | diffusion | (N/cm) |
| Example 1 | 21 | 3 | 0.14 | Double- | No | >100 |
| | | | | side | | |
| Example 2 | 15 | 3 | 0.20 | Double- | No | >100 |
| | | | | side | | |
| Example 3 | 12 | 3 | 0.25 | Double- | No | >100 |
| | | | | side | | |
| Comparative | 17.8 | 22.6 | 1.27 | Single- | No | <100 |
| Example 1 | | | | side | | |
| Comparative | 21 | 50 | 2.38 | Single- | No | <100 |
| Example 2 | | | | side | | |
| Comparative | 21 | — | — | Single- | YES | >100 |
| Example 3 | | | | side | | |

According to the results in Table 1, it can be seen that the retaining wall can prevent the diffusion of solder and maintain the fineness of the circuit pattern of the active metal brazing substrate. Further, when the thickness of the retaining wall is controlled to be lower than the thickness of the active metal layer, the active metal brazing substrate can have higher tensile strength.

Therefore, the double-side active metal brazing substrate of the present invention can achieve the effect of preventing the active metal layer from overflowing the patterned area without reducing the bonding force of the conductive metal layer (the tensile strength is greater than 100 N/cm). The double-side printing structure of the present invention does not affect the overall structural strength, has more functionality than the single-sided printing structure, and maintains a tensile strength greater than 100 N/cm.

### Beneficial Effects of the Embodiments

One of the beneficial effects of the present invention is that the double-side active metal brazing substrate and the manufacturing method thereof provided by the present invention can prevents solder from overflowing at high temperatures by virtue of the technical solution of “the retaining wall” and “the thickness of the retaining wall is lower than the thickness of the active metal layer”, thereby improving the bonding force between the ceramic substrate layer and the conductive metal layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A double-side active metal brazing substrate, comprising:
a ceramic substrate layer having a first surface and a second surface;
a first active metal layer disposed on the first surface;
a second active metal layer disposed on the second surface;
a first retaining wall surrounding and contacting the first active metal layer, wherein a thickness of the first retaining wall is less than a thickness of the first active metal layer;
a second retaining wall surrounding and contacting the second active metal layer, wherein a thickness of the second retaining wall is less than a thickness of the second active metal layer;
a first conductive metal layer disposed on the first active metal layer; and
a second conductive metal layer disposed on the second active metal layer.

2. The double-side active metal brazing substrate according to claim 1, wherein a thickness ratio of the first retaining wall to the first active metal layer is 0.10 to 0.95.

3. The double-side active metal brazing substrate according to claim 1, wherein the first retaining wall comprises aluminum oxide, magnesium oxide, zirconium oxide, silicon oxide, aluminum nitride or silicon nitride.

4. The double-side active metal brazing substrate according to claim 1, wherein a thickness of the first retaining wall is 1-5 micrometers.

5. The double-side active metal brazing substrate according to claim 1, wherein a width of the first retaining wall is 0.1 mm to 30 mm.

6. The double-side active metal brazing substrate according to claim 1, wherein a thickness of the first active metal layer is 10-50 micrometers.

7. A method for manufacturing a double-side active metal brazing substrate, comprising:
performing a patterning process to form a first retaining wall on a first surface of a ceramic substrate layer, and a second retaining wall on a second surface of the ceramic substrate layer, wherein the first retaining wall defines a first patterned area, and the second retaining wall defines a second patterned area;
forming a first active metal layer in the first patterned area, and forming a second active metal layer in the second patterned area;
disposing a first conductive metal layer on the first active metal layer, and disposing a second conductive metal layer on the second active metal layer; and
performing a brazing process to fix the first conductive metal layer to the ceramic substrate layer, and fix the second active metal layer to the ceramic substrate layer;
wherein a thickness of the first retaining wall is less than a thickness of the first active metal layer, and a thickness of the second retaining wall is less than a thickness of the second active metal layer.

8. The method according to claim 7, wherein a sintering temperature in the brazing process is 800-950° C.

9. The method according to claim 7, wherein a sintering pressure in the brazing process is less than 8×10⁻⁵ Torr.

10. The method according to claim 7, wherein a tensile strength of the double-side active metal brazing substrate is greater than 100 N/cm.
